(19) United States
(12) Patent Application Publication
(10) Pub. No.: US 2002/0114475 A1
(43) Pub. Date: Aug. 22, 2002

(54) Triple-channel stereo mixer cross-fader or triple-channel slide switch (TCSS)

(76) Inventor: Mark Peter Radewagen, Los Angeles, CA (US)

Correspondence Address: Mark Radewagen, 103 E. Luray Ave., Alexandria, VA, 22301-2027, US

(21) Appl. No.: 10/026,717

(22) Filed: Dec. 27, 2001

Related U.S. Application Data
(60) Provisional application No. 60/258,234, filed on Dec. 27, 2000.

(51) Int. Cl. H03G 7/00; H04B 1/00

(52) U.S. Cl. 381/119; 381/106

(57) ABSTRACT

The Triple-Channel Slide Switch connects three audio channels into a single mixing device, allowing the user to access any of these channels through the single stroke manipulation of one switch.

### BACKGROUND

1. Field of Invention

This invention relates to audio electronics, specifically disc jockey application or those who use audio channel mixers.

2. Description of Prior Art

The Cross-Fader.

Currently, audio mixers are fashioned with what is called a “cross-fader,” a simple slide switch device which allows for the blending of two separate audio sources into one “program,” or material heard by the audience. Typically, the “material” used by the disc jockey is music. The cress-fader moves from one channel of audio material into the second and then back to the first channel once more. In application, the disc jockey changes the audio material played on the first channel “on cue” or “off-program,” meaning that it can only be heard by the disc jockey in their headphones and not by the audience, while the material from the second channel plays in the program. By manipulating the cross-fader, the first channel volume is brought up and into the program while the second channel volume is simultaneously brought down and out of the program. This constitutes an audio “mix-”

More recent improvements.

It is essential to distinguish the TCSS from mixers currently available with the “cue-assign” option. As with the TCSS, more than two channels, or multiple channels, are available in the cue-assign setup. However, only two channels are available to the program at a time; a switch additional to the cross-fader must be toggled to shift between the multiple channels, and then the cross-fader is manipulated to bring the desired audio mix. So while there may be more than two sources available to the disc jockey, there is no performance “flow” between the multiple sources because the cross-fader can still only move between two channels. So, the faster a DJ is mixing, the more tedious the operation of multiple devices becomes. The TCSS allows fluid mixing through three channels with single-stroke single-device operation.

A device which has since advanced on the cue-assign in certain aspects allows more than two audio sources to be opened into the cross-fader at one time. However, the cross-fader is still the critically limiting device because it only moves back and forth between two channels, despite the fact that the number of audio sources has increased. With more than one audio source on each side of the channel, even more switches must be manipulated to bring in and take out multiple audio source material. This makes it even more precarious than the cue-assign setup, especially when the disc jockey's main priority is to change material on each source as they move back and forth between channels. The TCSS is supreme to this device because it offers three channels on one unit that are entirely independent of each other; three channels with the absolutely equal ability to mix into one another with one stroke, thanks to the triangular design. Instead of adding improvements to the mixer device, the TCSS is a direct improvement on the layout of the cross-fader itself, a previously unheard-of development.

### OBJECTS AND ADVANTAGES

Whereas the cross-fader, as cited in the Background—Description of Prior Art section, allows a disc jockey to mix between two channels, the Triple Channel Slide Switch or TCSS avails the disc jockey an immediate third-option channel. In other words, the TCSS offers three channels for use in the program through the manipulation of only one device. Both the cross-fader and TCSS offer single-device manipulation, but the cross-fader only offers two channels, while the TCSS features three channels.

### DRAWING FIGURES

FIG. 1 is a piece-by-piece breakdown of a typical TCSS.

FIG. 2A is a diagonal view of the TCSS, in complete form;

FIG. 2B is a typical cross-fader, the comparable ancestor to the TCSS, currently available.

FIG. 3 is a bird's eye view of the TCSS design.

FIGS. 4A to 4D chart the step-by-step functional breakdown of the pressure-locking mechanism (exploded) at the tip of any given point on the TCSS triangle, in use.

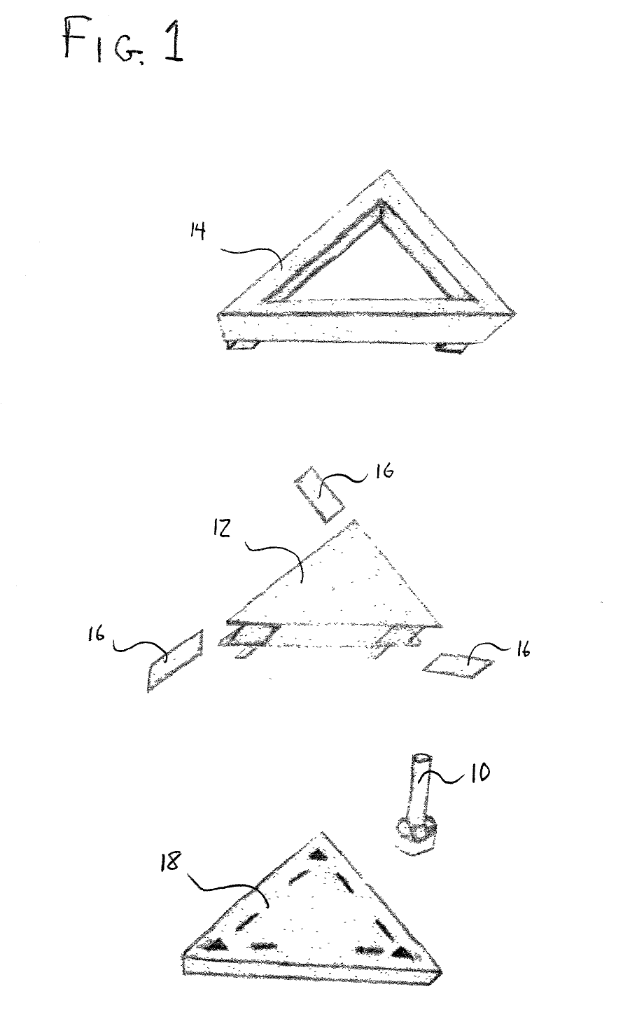

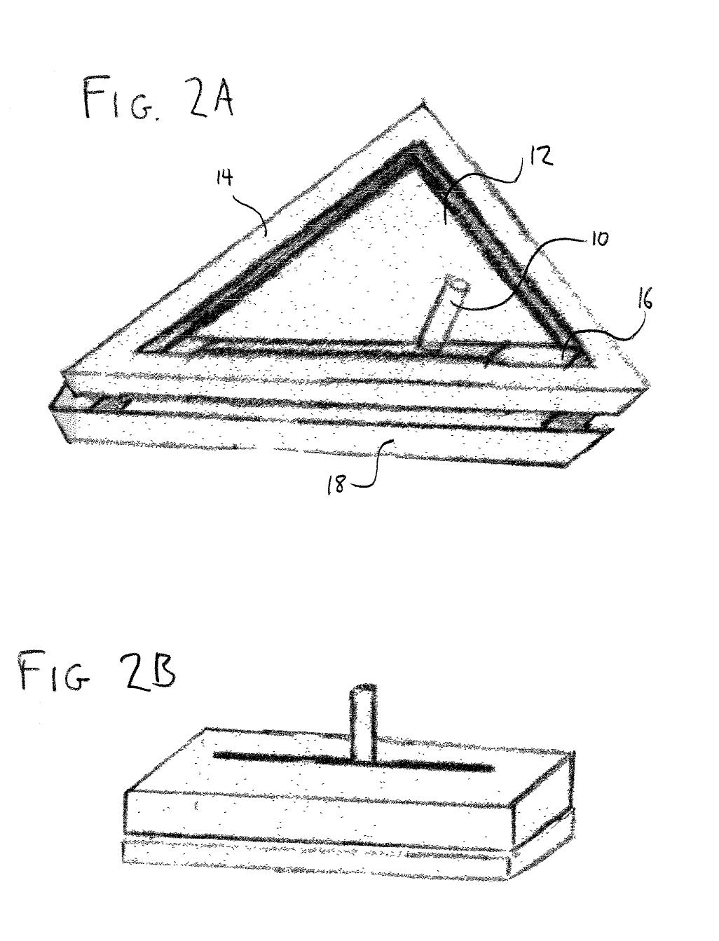

### REFERENCE NUMERALS IN DRAWINGS

| | |
|---|---|
| 10 switch | 12 inner switch guide |
| 14 outer switch guide | 16 locking turnstile (3) |
| 18 base track | |

Summary

The TCSS offers three channels through a single device. As the cross-fader's design has been improved from two channels to the three-channel setup on the triangular design, only the manipulation of this device is required to mix in multiple channels, effectively streamlining the process for a disc jockey in need of more than two channels of audio material in a brief amount of time.

Description

The main embodiment of the TCSS is performance disc jockey application, allowing the DJ to have an immediate third-option audio source available through the manipulation of only the slide switch on the TCSS.

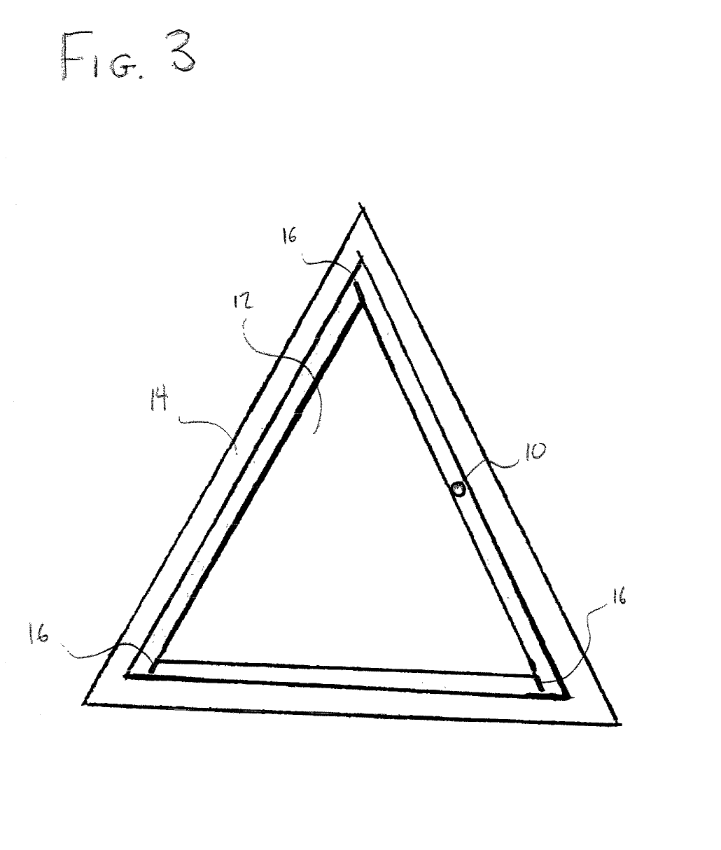

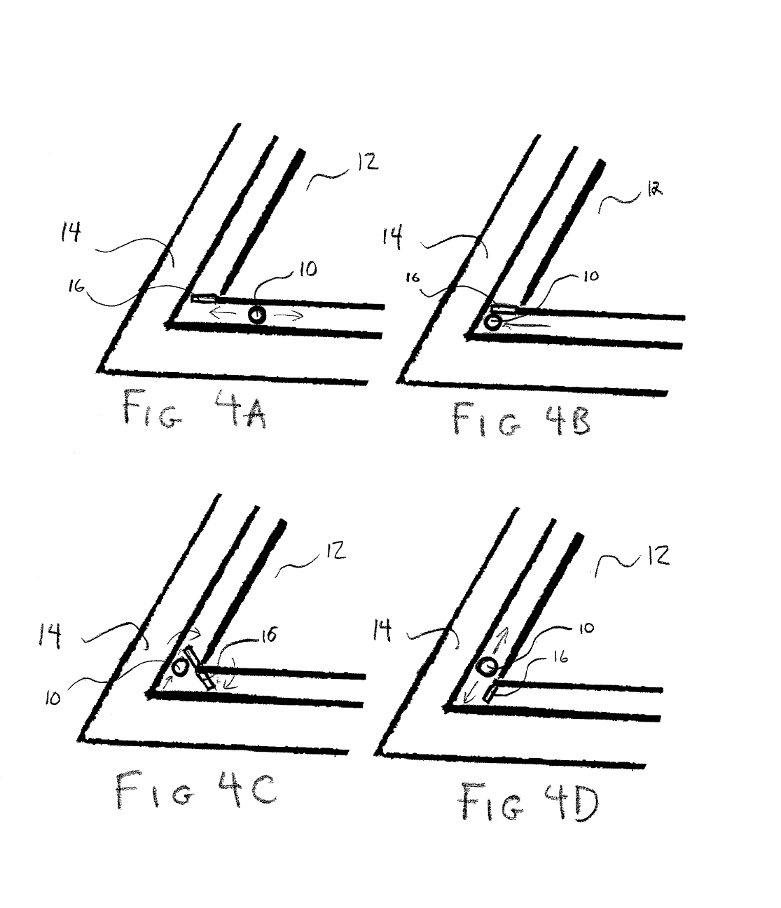

The switch (10) is guided from channel to channel by a single track running in triangular shape (12, 14, 18). The points of the triangle represent the three separate audio channels. When the switch is positioned at one of these points (FIG. 4B, 4C), the corresponding channel, A, B, or C, is the only audio source heard in the program. Midway between each of the points, the two corresponding channels “mix” (FIG. 3). Either channels A and B, A and C, or B and C, can be heard in the source. When positioned exactly in the center (FIG. 3), both channels can be heard equally. When the switch is slid towards one of the tips, the volume of the channel at the opposite point is brought down and, when moved to the opposite point, out of the program.

The program audio schematic for a cross-fader is the limited A-to-B-to-A setup. This means the user's only option while using channel B is to move back to channel A, and vice-versa. As previously stated, this is where the user will change the material on channel A, in cue, while channel B can be heard in the program, then use the cross-fader to bring into the program the material from channel A while the material in channel B is simultaneously taken out of the program. In contrast, the TCSS's program channel audio schematic is the formidable A-to-B/C-to-C/B/A setup. From channel A, the DJ has the option to go to audio sources on either channel B or channel C, and from there back to audio sources on either channel C, B, or A, depending upon which channel they opened in the second step. With this third channel always available in fluidity on the TCSS, the audio mixing options likewise multiply and the DJ always has two audio options available to them with the single-stroke manipulation of the switch, giving them more mixing options while at the same time simplifying the required device manipulations.

Operation

In practical use, the operation of the TCSS is as simple as the cross-fader setup. All further knowledge required to perform on the device by a lay disc jockey is gained from looking at it and moving it. The slide switch manipulation at the three points of the TCSS is the new feature, but is self-explanatory. Where the cross-fader switch manipulation is back and forth along a single track to “fade” in between two audio channels, two additional tracks are featured on the TCSS, connected at their points, to form an enclosed, exclusive three-channel track. As with the cross-fader, there is a single switch. This switch is slid across the channels and around the channel points to the channels desired for use.

In order to keep the switch from sliding unintentionally on to an adjoining track at the tip where two tracks meet at any of the three points on the TCSS, a “locking turnstile” (1b) along the guide infrastructure of the TCSS will effectively block off the path of the switch, preventing it from unintentionally sliding into the next track (FIGS. 4A, 4D). A small amount of pressure applied by the user will slide this wall out of the way (FIG. 4C), locking it in position to block off the track the in which slide switch was previously used (FIG. 4D).

Conclusion, Ramifications, and Scope

The TCSS will eventually render the cross-fader near-obsolete, because of the cross-fader's ultimately limited dual-channel setup. The disc jockey market has entered a new and innovative era in recent years, and the TCSS addresses such changes and new market demands. Because its use is similar to the cross-fader, as well as self-explanatory, it will be only a short matter of time before all serious performance DJs shift from the cross-fader to the TCSS, bottoming out the demand for mixers which feature only the dual-channel cross-fader.

1. Means for moving between more than two audio sources through the single-stroke manipulation of a single device.
